(19) United States
(12) Patent Application Publication
(10) Pub. No.: US 2007/0210805 A1
(43) Pub. Date: Sep. 13, 2007

(54) Insulation detecting method and insulation detecting device

(75) Inventor: Yoshihiro Kawamura, Shizuoka (JP)

Correspondence Address: KRATZ, QUINTOS & HANSON, LLP, 1420 K Street, N.W., Suite 400, WASHINGTON, DC, 20005, US

(73) Assignee: YAZAKI CORPORATION, Tokyo (JP)

(21) Appl. No.: 11/713,720

(22) Filed: Mar. 5, 2007

(30) Foreign Application Priority Data
Mar. 8, 2006 (JP) 2006-062388
Mar. 10, 2006 (JP) 2006-065829

(51) Int. Cl. G01R 31/02

(52) U.S. Cl. 324/541

(57) ABSTRACT

An alternating signal from a signal generator is applied to a direct current source via a detecting resistor and a coupling capacitor. A detecting member detects a voltage amplitude change appeared at a contact between the detecting resistor and the coupling capacitor. Based on the voltage amplitude change, a correction member corrects a first measuring voltage when a capacitor is connected to a contact between an anode of the direct current source and a ground, and a second measuring voltage when the capacitor is connected to a contact between a cathode of the direct current source and the ground. Based on the corrected first and second measuring values and a voltage across the direct current source when the capacitor is connected to the anode and the cathode of the direct current source by a voltage measuring member, a calculation member calculates a resistance between the direct current source and the ground.

### CROSS REFERENCE TO RELATED APPLICATIONS

This application is on the basis of Japanese Patent Applications No. 2006-062388, and No. 2006-065829 the contents of which are hereby incorporated by reference.

### BACKGROUND OF THE INVENTION

1. Field of the Invention

The present invention relates to an insulation detecting method and an insulation detecting device, in particular, for detecting a ground fault resistance of a direct current power source.

2. Description of the Related Art

As a conventional insulation detecting device, for example, a flying capacitor type insulation detecting device is proposed. This insulation detecting device detects an insulating state of a direct current high voltage power source by calculating a ground fault resistance based on a measured voltage of a high voltage charged capacitor floating from the ground (namely, a flying capacitor), and a measured voltage of a high voltage charged capacitor of which one electrode is connected to the earth via a resistor (for example, refer to Patent Document 1 and 2).

FIG. 7 is a circuit diagram showing a structure of a conventional insulation detecting device. In FIG. 7, V indicates a high voltage direct current power source in which the number N of batteries are connected in series. This high voltage power source V is insulated from a ground G of a low voltage system including a microcomputer 10.

As shown in FIG. 7, the insulation detecting device includes a bipolar capacitor C, a first switch SW1 for connecting an anode of the high voltage power source V insulated from the ground G to an end of the capacitor C, and a second switch SW2 for connecting a cathode of the high voltage source to an opposite end of the capacitor C.

The microcomputer 10 works as a voltmeter for measuring a voltage supplied to an input port A/D (=input terminal) by analog to digital conversion. The insulation detecting device includes a third switch SW3 for connecting an end of the capacitor C to the input port A/D, and a fourth switch SW4 for connecting the opposite end of the capacitor to the ground G.

The insulation detecting device further includes a first resistor R1 mounted between the third switch SW 3 at the input port A/D side and the ground G, and a second resistor R2 mounted between the fourth switch SW4 at the ground G side and the ground G.

A voltage is supplied to the input port A/D via a protection circuit 11. This protection circuit is composed of a protection resistor Rp1 mounted between the first resistor R1 at the third switch SW3 side and the input port A/D, and a clamping diode Dc mounted between the protection resistor Rp1 at the input port A/D side and the ground G.

The protection resistor Rp1 works as a current limiting resistor to prevent an overcurrent from flowing into the input port A/D. Further, the clamping diode protects the input port A/D from a high plus or minus voltage which may damage the microcomputer 10.

The insulation detecting device further includes a resistance switching circuit 12 mounted between a line between the first switch SW1 and the third switch SW3, and the capacitor C. The resistance switching circuit is structured by connecting two series circuit in parallel. One series circuit is connected to the line between the first switch SW1 and the third switch SW3 toward the capacitor C as a forward direction and composed of a first diode D1 and a first switching resistor Rc1. The other series circuit is composed of a second diode D2 connected in a direction opposed to the first diode D1 and a second switching resistor Rc2.

For example, photo MOS FETs are used as the first to fourth switches SW1 to SW4. They are isolated from the high voltage power source and controlled by the microcomputer 10. Incidentally, in a reset circuit 13, when a reset switch SWr is closed, charge charged in the capacitor C is rapidly discharged with a discharge resistor Rdc.

An operation of the insulation detecting device will be explained with reference to FIG. 8. First, the microcomputer 10 measures a high voltage V₀ of the high voltage source V (step S11). In detail, this measurement is done by followings. Initially, all the switches are open.

Then firstly, the microcomputer 10 closes the first and the second switches SW1, SW2 so that the voltage of the high voltage V is charged to the capacitor C.

Next, the microcomputer 10 opens the first and the second switches SW1, SW2, then closes the first and second switches SW1, SW2 to charge the all voltage of the high voltage power source to the capacitor C.

Next, the microcomputer 10 opens the first and the second switches SW1, SW2, then closes the third and the fourth switches SW3, SW4 to supply the voltage V₀ of the capacity C, namely, the high voltage power source V to the input port A/D of the microcomputer 10. Thus, the microcomputer 10 reads out the voltage V₀ as the voltage of the high voltage power source.

Next, the microcomputer 10 measures a voltage V_{RL-} corresponding to a value of a resistor RL− at the cathode side (step S12). In detail, this measurement is done as followings. After the reset circuit 13 resets, the microcomputer 10 closes the first and the fourth switches SW1, SW4. Thus, a voltage corresponding to the value of the resistor RL− is charged to the capacitor C.

Next, the microcomputer 10 opens the first switch SW1, and then closes the third and the fourth switches SW3, SW4. Thus, the microcomputer 10 reads out a voltage across the capacitor C, namely, the voltage V_{RL} corresponding to the value of the resistor RL−.

Next, the microcomputer 10 measures a voltage V_{RL+} corresponding to a value of a resistor RL+ at an anode side (step S13). In detail, this measurement is done as followings. The microcomputer 10 resets with the reset circuit 13, then closes the second and the third switches SW2, SW3. Thus, a voltage corresponding to a value of the resistor RL+ is charged in the capacitor C.

Next, the microcomputer 10 closes the second switch SW2, and then closes the third and the fourth switches SW3, SW4. Thus, the microcomputer 10 reads out the voltage across the capacitor, namely, the voltage V_{RL+} corresponding to the value of the resistor RL+.

Next, the microcomputer 10 calculates to dividing a sum of adding V_{RL-} and V_{RL+} by a measurement voltage V₀ (V_{RL-}+V_{RL+}/V₀) (step S14). Next, the microcomputer 10 calculates a resistance of the high voltage source V to the ground using the quotient and a conversion table between the quotient and the resistance previously stored in an internal memory (step S15).

Thus, the microcomputer 10 can detect an insulation condition of the high voltage source V by reading out the voltage across the capacitor C every time when the capacitor C is charged in V₀, V_{RL+}, or V_{RL-} by controlling the first to fourth switches SW1 to SW4.

[Patent Document 1] Japanese published patent application No. 2004-170103.

[Patent Document 2] Japanese published patent application No. 2004-245632.

Incidentally, in a vehicle having a high voltage direct current source such as an electric powered vehicle, from a point of safety, there is a demand that the isolation between the high voltage source and the ground be determined any time without influenced by a running condition of the vehicle. However, in the vehicle having the high voltage source, the high voltage changes owing to the running condition.

FIG. 9 shows a change of the high voltage of the high voltage source in a vehicle. As shown in FIG. 9, in a period from turning an engine on to starting running, the high voltage is constant so that this period is suitable for detecting the insulation. After the vehicle is running, the high voltage is decreased when a load increases (when an acceleration is on), and is increased when braking. Further, when inertia running (stable running), the high voltage is constant.

FIG. 10 shows a change of the voltage across the capacitor C in an insulation detecting cycle. As shown in FIG. 10, when the high voltage is changed, in a charging waveform from time t1 for measuring the voltage V₀ across the high voltage source V, a charging waveform from time t2 for measuring the voltage V_{RL-} and a charging waveform from time t3 for measuring the voltage V_{RL-}, the capacitance C is respectively charged by different high voltage V. Thus, when the insulation is detected under the change of the high voltage, because the voltage V₀ across the high voltage source V is changed at the respective measuring timing started from t1, t2, t3, a result calculated by an equation (V_{RL-}+V_{RL+}/V₀) is not a correct value, and an accurate insulation detection cannot be done. Accordingly, the insulation is hardly detected while a vehicle is running.

Thus, because the insulation is not detected accurately while the high voltage changes, the insulation is detected only when the vehicle is stopped, or stably running.

However, an electric shock may occur when the vehicle is running. Therefore, there is a safety problem and a pending problem of changing the high voltage in an insulation detecting device.

Accordingly, an object of the present invention is to provide an insulation detecting method and an insulation detecting device to be able to detect an insulation resistance in all of vehicle running conditions.

### SUMMARY OF THE INVENTION

In order to attain the object, according to the present invention, there is provided an insulation detecting method for detecting a resistance between a ground and an insulated direct current source including the steps of:

a first measurement step to determine a voltage V₀ across the direct current source by measuring a voltage across a capacitor connected to an anode and a cathode of the direct current voltage source;

a second measurement step to determine a first measurement voltage V_{RL-} by measuring a voltage across a capacitor connected to the anode of the direct current voltage source and the ground;

a third measurement step to determine a second measurement voltage V_{RL+} by measuring a voltage across a capacitor connected to the cathode of the direct current voltage source and the ground;

a detecting step to apply an alternating signal to the anode or the cathode of the direct current source via a detecting resistor and a coupling capacitor and to detect a change of a voltage amplitude of the alternating signal appeared across the detecting resistance as a voltage change of the direct current source;

a correction step to calculate a corrected first measurement voltage V_{RL-}′ by correcting the first measurement voltage V_{RL-} calculated at the second measurement step based on the voltage change of the direct current source detected at the detecting step, and to calculate a corrected second measurement voltage V_{RL+}′ by correcting the second measurement voltage V_{RL+} calculated at the third measurement step, and a resistance calculating step for calculating a resistance between the direct current source and the ground based on the corrected first measurement voltage V_{RL-}′, the corrected second measurement voltage V_{RL+}′ calculated at the correction step, and the voltage V₀ across the direct current source calculated at the first measurement step.

Preferably, the detecting step including:

a first average measurement step to measure a first average of a voltage amplitude of the alternating signal appeared across the detecting resistance while the first measurement step proceeds;

a second average measurement step to measure a second average of the voltage amplitude of the alternating signal appeared across the detecting resistance while the second measurement step proceeds;

a third average measurement step to measure a third average of the voltage amplitude of the alternating signal appeared across the detecting resistance while the third measurement step proceeds; and

a correction value calculating step to calculate a ratio of the first average to the second average as a first correction value corresponding to the voltage change across the direct current source and to calculate a ratio of the first average to the third average as a second correction value corresponding to the voltage change across the direct current source,

wherein the correction step calculates the corrected first measurement voltage V_{RL-}′ by correcting the first measurement voltage V_{RL-} based on the first correction value, and calculates the corrected second measurement voltage V_{RL+}′ by correcting the second measurement voltage V_{RL+} based on the second correction value, and the resistance calculating step calculates the resistance between the direct current source and the ground based on the corrected first measurement voltage V_{RL-}′, the corrected second measurement voltage V_{RL+}′, and the voltage V₀ across the current voltage source.

Another aspect of the invention, there is provided an insulation detecting device for detecting a resistance between a ground and an insulated direct current source including:

a capacitor;

a voltage measuring member for measuring a voltage across the capacitor;

a first switch connected between an anode of the direct current source and one end the capacitor;

a second switch connected between a cathode of the direct current source and an opposite end of the capacitor;

a third switch connected between the one end of the capacitor and the voltage measuring member;

a fourth switch connected between an opposite end of the capacitor and the ground;

a control member for selectively closing the first to fourth switches,

an alternating signal generating member;

a detecting resistor and a coupling capacitor for applying an alternating signal generated by the alternating signal generator to the direct current source;

a detecting member for detecting a fluctuation component of a voltage amplitude of the alternating signal appeared across the detecting resistor as a change of the voltage across the direct current source;

a correction member for calculating a corrected first measurement voltage V_{RL-}′ by correcting a first measurement voltage V_{RL-} measured by measuring a voltage with the voltage measuring member across the capacitor charged by the controlling member closing the first and the fourth switches, and for calculating a corrected second measurement voltage V_{RL+} by correcting a second measurement voltage V_{RL+} measured by measuring the voltage of the capacitor charged by the controlling member closing the second and the third switches based on the change of the voltage across the direct current source; and

a calculating member for calculating a resistance between the direct current source and the ground based on the corrected first measurement voltage V_{RL-}′, the corrected second measurement voltage V_{RL+}′, and a voltage across the direct current source V₀ measured by measuring the voltage across the capacitor charged by the controlling member closing the first and the second switches.

Preferably, the detecting member includes:

a first average measuring member for measuring a first average of a voltage amplitude of the alternating signal appeared across the detecting resistor while the voltage measuring member measures the voltage V₀ across the direct current source;

a second average measuring member for measuring a second average of the voltage amplitude of the alternating signal appeared across the detecting resistor while the voltage measuring member measures the first measurement voltage V_{RL-};

a third average measuring member for measuring a third average of the voltage amplitude of the alternating signal appeared across the detecting signal while the voltage measuring member measures the second measurement voltage V_{RL+}; and

a correction value calculating member for calculating a ratio of the first average to the second average as a first correction value corresponding to the change of the voltage across the current voltage source, and for calculating a ratio of the first average to the third average as a second correction value corresponding to the based on the change of the voltage across the direct current source,
the correction member calculates the corrected first measurement voltage V_{RL-}′ by correcting the first measurement value V_{RL-} based on the first correction value, and calculates the corrected second measurement value V_{RL+} by correcting the second measurement value V_{RL+} based on the second correction value, and

the resistance calculating member calculates the resistance between the direct current source and the ground based on the corrected first measurement voltage V_{RL-}′, the corrected second measurement voltage V_{RL+}′, and the voltage V₀ across the direct current source.

Preferably, the insulation detecting device further includes:

a first resistor connected between a contact between the third switch and the voltage measuring member and the ground;

a second resistor connected between the fourth switch and the ground;

a first and a second switching resistors connected between a contact between the first and the third switches and one end of the capacitor; and

a selecting member for selecting one of the first and the second switching resistors corresponding to a polarity direction of the capacitor, and connecting the one of the first and the second switching resistors between the contact between the first and the third switches and the one end of the capacitor.

According to another aspect of the invention, there is provided an insulation detecting method for detecting a resistance between a ground and an insulated direct current source including the steps of:

a first measurement step to determine a first measurement voltage V_{RL-} by a first voltage measuring member measuring a voltage across a capacitor connected to an anode of the direct current voltage source and the ground;

a second measurement step to determine a second measurement voltage V_{RL+} by the first voltage measuring member measuring a voltage across the capacitor connected to a cathode of the direct current voltage source and the ground;

a third measurement step to determine a voltage V₀′ across the direct current source by a second voltage measuring member connected to both ends of the direct current source while the first and the second measuring steps proceed; and

a calculating step for calculating a resistance between the direct current source and the ground based on the first voltage V_{RL-}, the second voltage V_{RL+}, and the voltage V₀′ across the direct current source.

Another aspect of the invention, there is provided an insulation detecting device for detecting a resistance between a ground and an insulated direct current source comprising:

a capacitor;

a first voltage measuring member for measuring a voltage across the capacitor;

a first switch connected between an anode of the direct current source and one end the capacitor;

a second switch connected between a cathode of the direct current source and an opposite end of the capacitor;

a third switch connected between the one end of the capacitor and the first voltage measuring member;

a fourth switch connected between the opposite end of the capacitor and the ground;

a control member for selectively closing the first to fourth switches;

a second measuring member connected to both ends of the direct current source for measuring a voltage V₀′ across the direct current source; and

a calculating member for calculating a resistance between the direct current source and the ground based on a first measurement voltage V_{RL-} measured by measuring a voltage with the voltage measuring member across the capacitor charged by the controlling member closing the first and the fourth switches, a second measurement voltage V_{RL+} measured by measuring the voltage of the capacitor charged by the controlling member closing the second and the third switches, and the voltage V₀′ across the direct current source,

wherein the second measuring member measures the voltage V₀′ across the direct current source while the first measuring member measures the first measurement voltage V_{RL-} and the second measurement voltage V_{RL+}′.

Preferably, the insulation detecting device further includes:

a first resistor connected between a contact between the third switch and the first voltage measuring member and the ground;

a second resistor connected between the fourth switch and the ground;

a first and a second switching resistors connected between a contact between the first and the third switches and one end of the capacitor; and

a selecting member for selecting one of the first and the second switching resistors corresponding to a polarity direction of the capacitor, and connecting the one of the first and the second switching resistors between the contact between the first and the third switches and the one end of the capacitor.

These and other objects, features, and advantages of the present invention will become more apparent upon reading of the following detailed description along with the accompanied drawings.

### BRIEF DESCRIPTION OF THE DRAWINGS

FIG. 1 is a circuit diagram showing a first embodiment of an insulation detecting device carrying out an insulation detecting method according to the present invention;

FIG. 2 is a flowchart explaining an operation of the insulation detecting device shown in FIG. 1;

FIG. 3 is a waveform chart explaining the operation of the insulation detecting device shown in FIG. 1;

FIG. 4 is a circuit diagram showing a second embodiment of an insulation detecting device carrying out an insulation detecting method according to the present invention;

FIG. 5 is a block diagram showing a structure of a high voltage measuring circuit of the insulation detecting device shown in FIG. 4;

FIG. 6 is a flowchart explaining an operation of the insulation detecting device shown in FIG. 4;

FIG. 7 is a waveform chart explaining the operation of the insulation detecting device shown in FIG. 4;

FIG. 8 is a circuit diagram showing another structure of the high voltage measuring circuit of the insulation detecting device shown in FIG. 4;

FIG. 9 is a circuit diagram showing a structure of a conventional insulation detecting device;

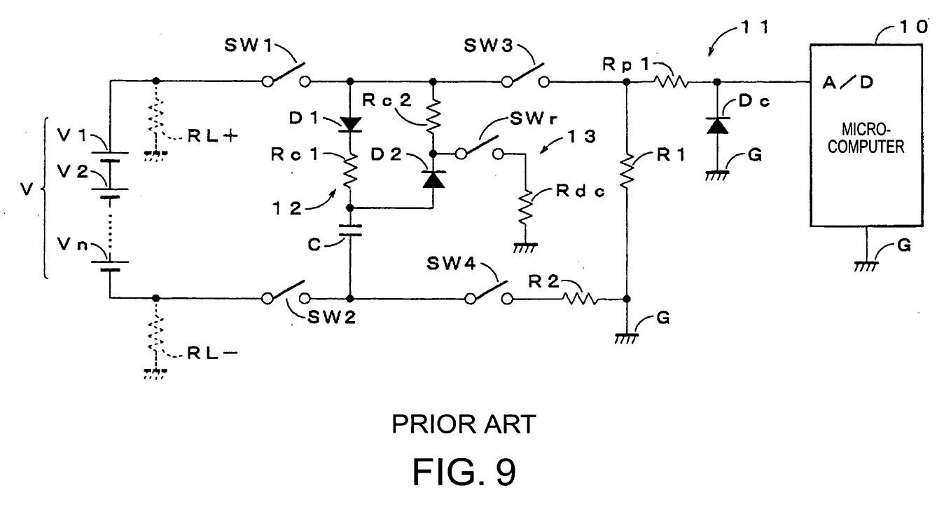

FIG. 10 is a flowchart explaining an operation of the insulation detecting device shown in FIG. 9;

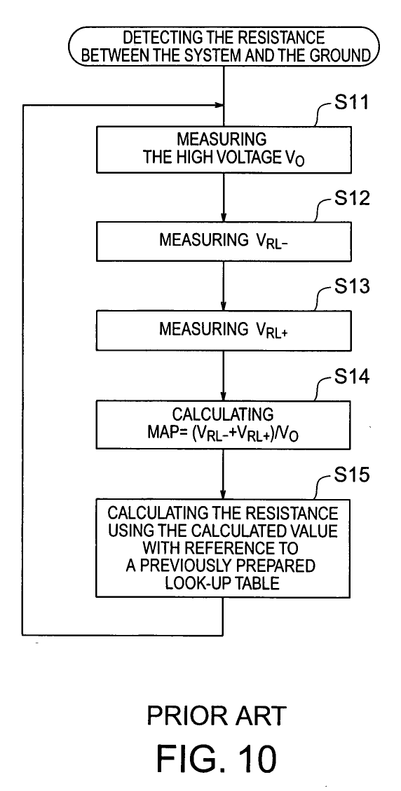

FIG. 11 is a graph showing an image of a change of a high voltage of a high voltage source in a vehicle;

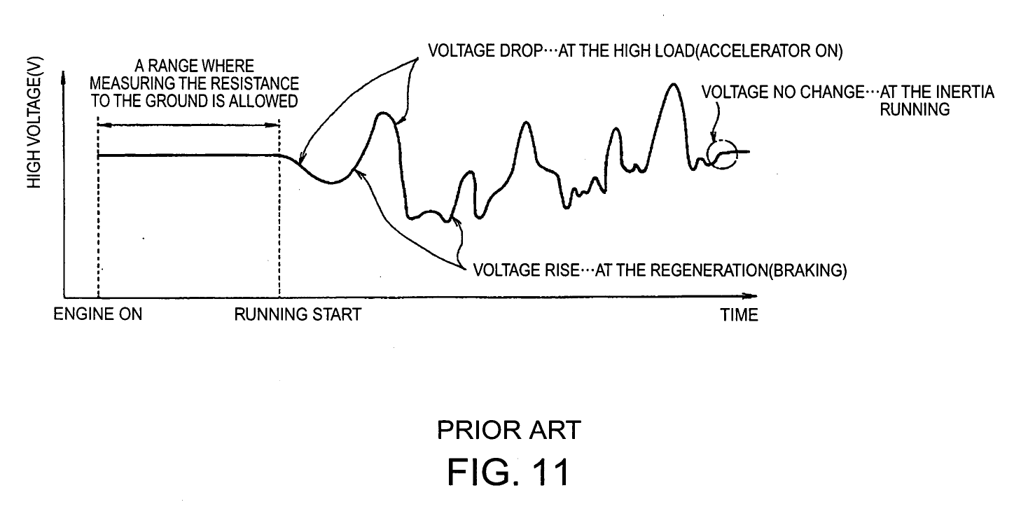

FIG. 12 is a graph showing a change across a capacitor in a insulation detecting cycle in the insulation detecting device shown in FIG. 9.

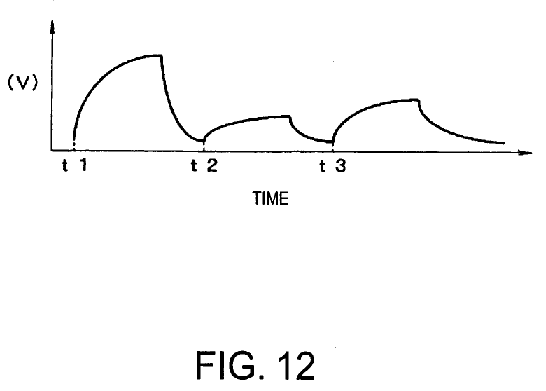

### DETAILED DESCRIPTION OF THE PREFERRED EMBODIMENTS

### First Embodiment

A first embodiment of an insulation detecting method and an insulation detecting device will be explained with reference to figures.

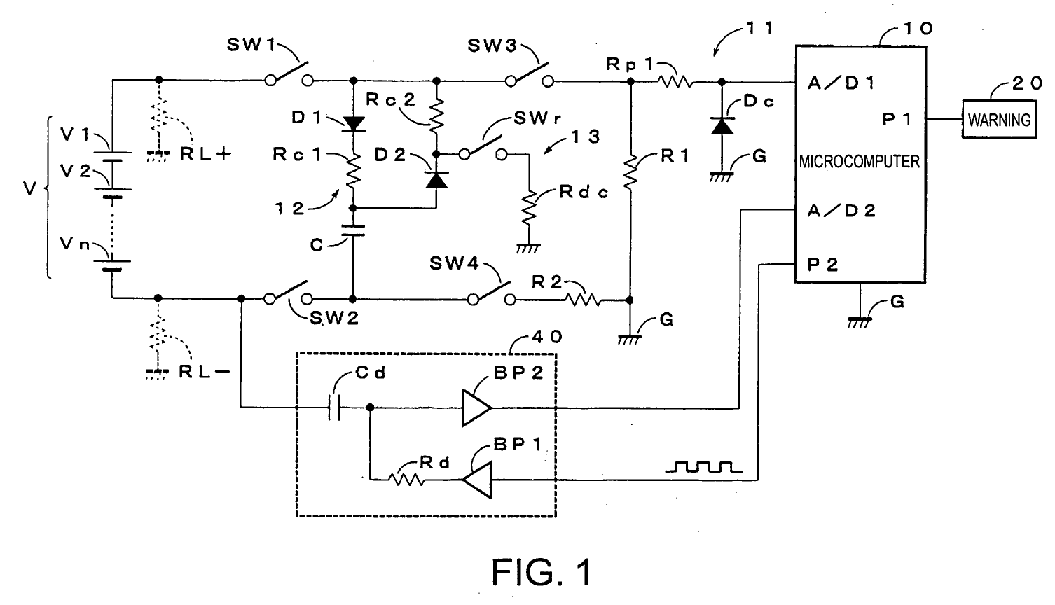

FIG. 1 is a circuit diagram showing a first embodiment of an insulation detecting device carrying out an insulation detecting method according to the present invention. A high voltage source (=direct current source) V composed of the number N of the batteries in series is isolated from a ground G of a low voltage system such as a microcomputer 10. The microcomputer 10 works as a voltage measuring member, a controlling member, an alternating signal generating member, a detecting member, a correction member, a resistance calculating member, a first average value measuring member, a second average value measuring member, a third average value measuring member, and a correction value calculating member in claims.

As shown in FIG. 1, the insulation detecting device includes a structure of a flying capacitor system, and includes a bipolar capacitor C, a first switch SW1 for connecting an anode of the high voltage source V to an end of the capacitor C, and a second switch SW2 for connecting a cathode of the high voltage source V to the opposite end of the capacitor C.

The microcomputer 10 measures a voltage by A/D converting a voltage supplied to input ports A/D1 and A/D2. Further, the microcomputer 10 includes an output port P1 for driving a warning part 20 when an insulation failure is detected. Further, the microcomputer 10 includes an output port 2 for outputting a square wave as an alternating signal. The insulation detecting device includes a third switch SW3 for connecting the one end of the capacitor to the input port A/D1, and a fourth switch SW4 for connecting the opposite end of the capacitor to the ground G.

The insulation detecting device also includes a first resistor R1 interposed between the third switch SW3 at the input port A/D1 side and the ground G, and a second resistor R2 interposed between the fourth switch SW4 at the ground G side and the ground G.

Further, a voltage is supplied to the input port A/D1 via a protection circuit 11. This protection circuit 11 includes a protection resistor Rp1 interposed between the first resistor R1 at the third switch SW3 side and the input port A/D1, and a clamp diode Dc interposed between the protection resistor Rp1 at the input port A/D1 side and the ground G.

The protection resistor Rp1 works as a current limiting resistor and protects the input port A/D1 from an overcurrent. Further, the clamp diode Dc protects the input port A/D1 from a huge positive or negative voltage.

The insulation detecting device includes a resistor switching circuit 12 interposed between a contact between the first and the third switches SW1, SW3 and the capacitor C. The resistor switching circuit 12 is structured by connecting series circuits in parallel. One series circuit is composed of a first diode D1 connected in a forward direction from the contact between the first and the third switches SW1, SW3 to the capacitor C, and a first switching resistor Rc1. The other series circuit is composed of a second diode connected in a reverse direction against the first diode D1, and a second switching resistor Rc2.

Namely, the first and the second diodes D1, D2 works as a selecting member. The selecting member selects one of the first and the second switching resistor corresponding to the polarity direction of the capacitor, and connects the selected resistor to the contact between the contact between the first and the third switches SW1, SW3, and the capacitor C. Further, the switches SW1 to SW4 are controlled by the microcomputer 10 with, for example, an optical MOSFET for isolating from the high voltage source V. Incidentally, a reference number 13 indicates a reset circuit. When a reset switch SWr is closed, charge stored in the capacitor C can be rapidly discharged through a discharge resistor Rdc.

Further, the insulation detecting device includes a detecting circuit for a voltage amplitude change 40 for detecting the voltage across the high voltage source V. The detecting circuit for a voltage amplitude change 40 includes: a series circuit composed of a coupling capacitor Cd connected to an anode or a cathode of the high voltage source (the cathode in this embodiment) and a detecting resistor Rd; a buffer amplifier BP1 for amplifying a square wave outputted from an output port P2 of the microcomputer 10 and supplying the amplified signal to the series circuit; and a buffer amplifier BP2 for amplifying a square wave appeared at a contact between the coupling capacitor Cd and the detecting resistor Rd, and supplying the amplified signal to the input port A/D2 of the microcomputer 10. This detecting circuit for a voltage amplitude change 40 has a same structure and a same operation as a conventional AC coupling insulation detecting device, and detects the change of the voltage amplitude across the high voltage source V.

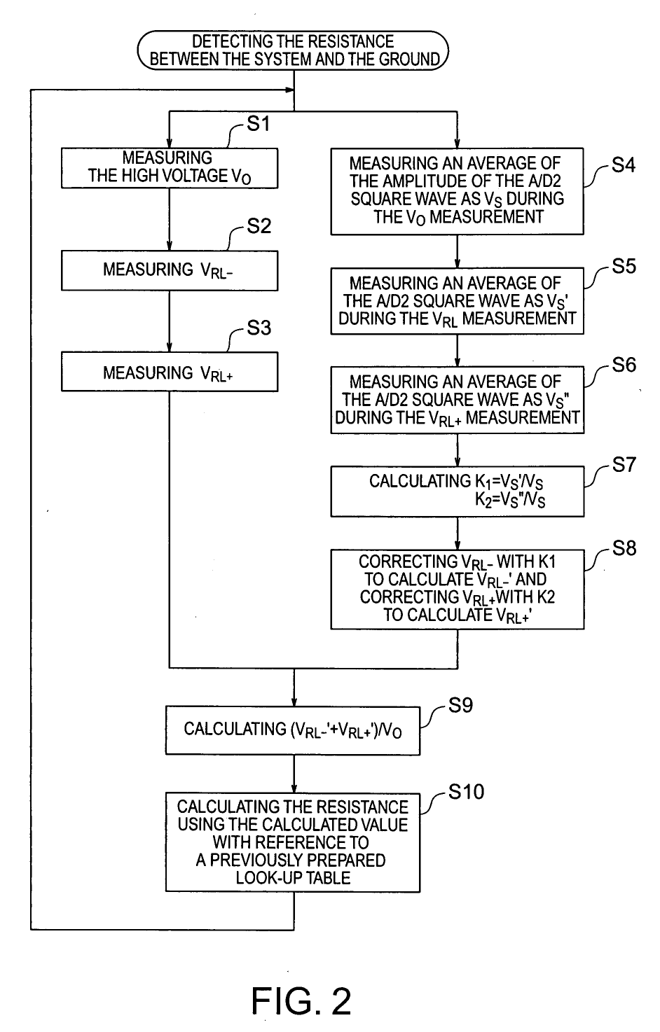

Next, a insulation detecting operation of the insulation detecting device according to the present invention will be explained with reference to a flowchart of FIG. 2. The flowchart of FIG. 2 includes steps S1 to S10. Steps S1 to S3 correspond to first to third measurement steps in claims. Steps S4 to S6 correspond to the detecting step and the detecting member in claims. Steps S7 and S8 correspond to the correcting step and the correcting member in claims. Steps 9 and 10 correspond to the resistance calculating step and the resistance calculating member. Further, the steps S4 to S6 respectively correspond to first to third average measuring steps and average measuring member. The step 7 corresponds to the correction value calculating step and the correction value calculating member.

First, the microcomputer 10 measures the voltage V₀ across the high voltage source V (step S1). This measurement is operated below. Initially, all the switches are open. Then, the microcomputer 10 closes the first and the second switches SW1, SW2 for a charging time T1. Incidentally, the time T1 is shorter than a time necessary for fully charging the capacitor C. Thus, a closed circuit is formed with the anode of the high voltage source V, the first switch SW1, the first diode D1, the first switching resistor Rc1, the capacitor C, the second switch SW2, and the cathode of the high voltage source V, and the capacitor C is charged by the high voltage source. In this case, the capacitor C is charged while being isolated from the ground G.

Next, after the first and the second switches SW1, SW2 are open, the third and the fourth switches are closed. Thus, a closed circuit is formed by the capacitor C, the second diode D2, the second switching resistor Rc2, the third switch SW3, the first and the second resistor R1, R2, and the fourth switch SW4. A value corresponding to the voltage across the capacitor C is supplied to the input port A/D1 of the microcomputer 10. At this time, the voltage Vc across the capacitor C, namely, the voltage V₀ across the high voltage source V is divided by a ratio determined by the second switching resistor Rc2, the first and the second resistor R1, R2, and supplied to the input port A/D1 of the microcomputer 10. Then, the divided voltage (Vc*R1/(Rc2+R1+R2)) is A/D (analog to digital) converted, and the value is inputted into the microcomputer 10 as the voltage V₀ of the high voltage source V.

Next, the microcomputer 10 measures a voltage V_{RL-} corresponding to the value of the resistor RL− (step S2). This measurement is in detail done by followings. The microcomputer 10 closes the reset switch SWr of the reset circuit 13 to fully discharge the capacitor C. Next, the microcomputer 10 opens the reset switch SWr and the third switch SW3, then closes the first and the fourth switches SW1, SW4 for a charging time T1. Thus, a close circuit is formed by the anode of the high voltage source, the first switch SW1, the first diode D1, the first switching resistor Rc1, the capacitor C, the fourth switch SW4, the second resistor R2, the ground G, the resistor RL−at the cathode side of the high voltage source V, and the cathode of the high voltage source. The voltage corresponding to the resistor RL−is charged in the capacitor C.

Next, the microcomputer 10 opens the first switch SW1, then closes the third and the fourth switches SW3, SW4. Thus, a closed circuit is formed by the capacitor C, the second diode D2, the second switching resistor Rc2, the third switch SW3, the first resistor R1, the second resistor R2, and the fourth switch SW4. Thus, the voltage Vc across the capacitor C is divided by a ratio determined by the second switching resistor Rc2, the first resistor R1, the second resistor R2, and supplied to the input port A/D1 of the microcomputer 10. The divided voltage is A/D converted, and the converted value is inputted into the microcomputer 10 as the voltage V_{RL-} (first measuring voltage) corresponding to the resistor RL−.

Next, a voltage V_{RL+} corresponding to the value of the resistor RL+ is measured (step S3). This measurement is in detail done by followings. The microcomputer 10 closes the reset switch SWr of the reset circuit 13 to fully discharge the capacitor C. Next, the microcomputer 10 opens the reset switch SWr and the fourth switch SW4, then closes the second and the third switches SW2, SW3 for the charge time T1. Thus, a closed circuit is formed by the anode of the high voltage source V, the resistor RL+, the ground G, the first resistor R1, the third switch SW3, the first diode D1, the first switching resistor Rc1, the capacitor C, the second switch SW2, and the cathode of the high voltage source. Thus, the voltage corresponding to the value of the resistor RL+ is charged to the capacitor C.

Next, the microcomputer 10 opens the second switch SW2, then closes the third and the fourth switches SW3, SW4. Thus, the voltage Vc across the capacitor C is divided by a ratio determined by the second switching resistor Rc2, the first resistor R1, and the second resistor R2, and supplied to the input port A/D1 of the microcomputer 10. The divided voltage is A/D converted and inputted to the microcomputer 10 as a voltage V_{RL+} (second measuring voltage) corresponding to the value of the resistor RL+.

Incidentally, the values of the first and the second resistors R1, R2 are the same (R1=R2). Thus, the charging resistor (Rc1+R2) when the first and the fourth switches SW1, SW4 are closed and the capacitor C is charged by the voltage corresponding to the resistor RL− and the charging resistor (Rc1+R1) when the second and the third switches SW2, SW3 are closed and the capacitor C is charged by the voltage corresponding to the resistor RL+ are the same.

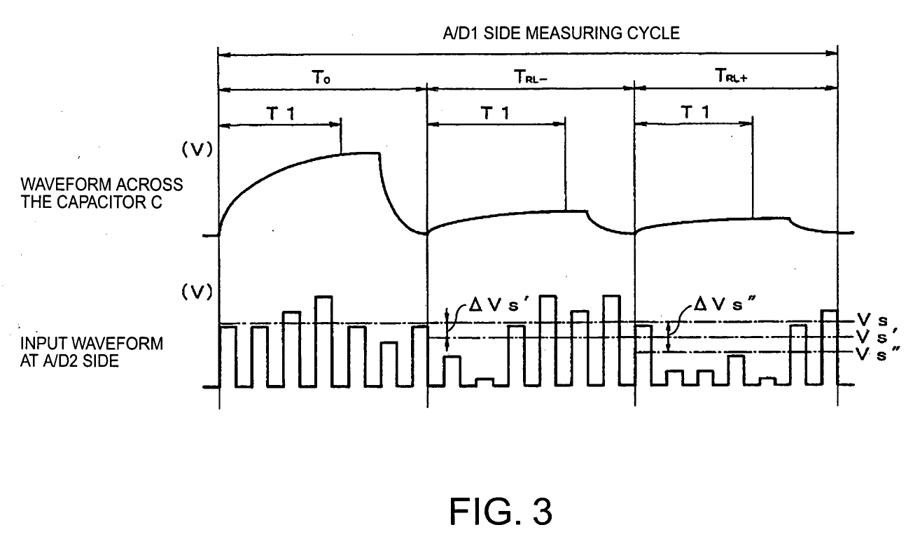

On the other hand, as shown in FIG. 3, during a measurement time T₀ for measuring the voltage V₀ across the high voltage source, the microcomputer 10 fetches an output of the detecting circuit for the voltage amplitude change 40 from the input port A/D2. Namely, when the square wave outputted from the output port P2 of the microcomputer 10 is supplied to the cathode of the high voltage source via the buffer amp BP1 and the coupling capacitor Cd, an amplitude of the square wave appeared at a contact between the coupling capacitor Cd and the detecting resistor Rd is influenced by the change of the resistor to the ground and an amplitude change component of the high voltage of the high voltage source V. The microcomputer 10 fetches the square wave of which amplitude is influenced from the input port A/D2 via the buffer amp BP2 at a sampling timing of a half interval of a cycle of the square wave. The voltage amplitudes of the sampled square wave are averaged and fetched by the microcomputer 10 as an average amplitude voltage Vs (first average) (step S4). The step S4 corresponds to the first average measuring member in claims.

At this time, assuming that no change of the resistor to the ground exists during the voltage measuring cycle at the A/D1 side, only an amplitude change component of the voltage across the high voltage source V relates to the voltage amplitude change of the square wave supplied to the input port A/D2. Therefore, the average amplitude voltage Vs (first average) measured as described above reflects the voltage amplitude change of the voltage V₀ across the high voltage source V during the measuring period T₀.

Next, similarly, during a measurement time T_{RL-} for measuring the voltage V_{RL-} corresponding to the resistor RL−, the microcomputer 10 fetches the output of the detecting circuit for the voltage amplitude change 40 from the input port A/D2. The voltage amplitudes of the sampled square wave are averaged and inputted to the microcomputer 10 as an average amplitude voltage Vs′ (second average) (step S5). The step S5 corresponds to the second average measuring member in claims. The measured average amplitude voltage Vs′ (second average) similarly reflects the voltage amplitude change of the voltage V₀ across the high voltage source during the measuring period T_{RL}.

Next, similarly, the microcomputer 10 fetches the output of the detecting circuit for a voltage amplitude change 40 from the input port A/D2 during a measuring period T_{RL+} for measuring the voltage V_{RL+} corresponding to the resistor RL+. The voltage amplitudes of the sampled square wave are averaged, and inputted into the microcomputer 10 as an average amplitude voltage Vs″ (third average) (step S6). The step S6 corresponds to the third average measuring member in claims. Similarly, the measured average amplitude voltage Vs″ (third average) reflects the voltage amplitude change of the voltage V₀ across the high voltage source during the measuring period T_{RL+}.

Next, the microcomputer 10 calculates a ratio K1 of the average amplitude voltages Vs and the Vs′ (=Vs/Vs′) and a ratio K2 of the average amplitude voltages Vs and Vs″ (=Vs/Vs″) (step S7). The step S7 corresponds to the correction value calculating member in claims. The calculated ratios K1, K2 are grasped as values indicating amplitude change of the high voltage of the high voltage source during the detection of the resistors to the ground. The ratios K1 and K2 respectively correspond to the first and the second correction value in claims.

Next, the microcomputer 10 corrects the measuring voltage V_{RL-} for removing the influence of the voltage change across the high voltage source based on the ratio K1 (first correcting value), and calculates the corrected measuring voltage V_{RL-}′ (=k1*V_{RL-}). Further, the microcomputer 10 corrects the measuring voltage V_{RL+} for removing the influence of the voltage change across the high voltage source based on the ratio K2 (second correcting value), and calculates the corrected measuring voltage V_{RL+}′ (=k2*V_{RL+}) (step S8).

Next, the microcomputer 10 calculates (V_{RL-}′+V_{RL+}′/V₀) (step S9). Next, the microcomputer 10 calculates the resistance between the high voltage source V and the ground by referring a look-up table of the calculated value and the resistance to the ground previously stored in the internal memory (step S10).

Thus, the microcomputer 10 calculates the resistance between the high voltage source V and the ground. After calculating the resistance, the microcomputer 10 compares the calculated resistance with a threshold value previously stored in the internal memory. If the calculated resistance is smaller than the threshold value, a warning part 20 warns that there is an insulation failure.

As mentioned above, the insulation detecting device of the flying capacitor system according to the invention has a better detecting accuracy than an insulation detecting device of the AC coupling system, and has a high noise tolerance noise due to an existence of a software processing by the microcomputer 10. Further, the insulation detecting device of the present invention includes the detecting circuit for a voltage amplitude change 40 having a structure and an operation similar to those of the insulation detecting device of the AC coupling system having a rapid response. Therefore, the insulation detecting device of the present invention can use data about the high voltage change of the high voltage source V, and detect the insulation at every vehicle running state including the state of changing the voltage of the high voltage source V that conventionally cannot be measured.

In the above embodiment, the signal supplied to the detecting circuit for a voltage amplitude change 40 from the output port P2 of the microcomputer 10 is a square wave. However, any signal which can detect the amplitude change may be used, for example, a sine wave.

### Second Embodiment

An insulation detecting device and an insulation detecting method according to the second embodiment of the present invention will be explained with figures.

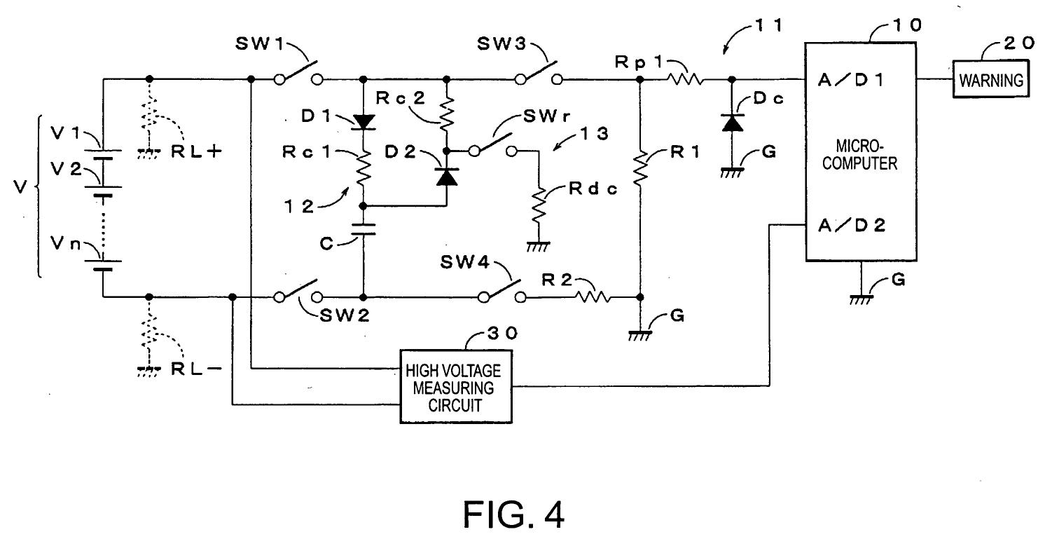

FIG. 4 is a circuit diagram showing a second embodiment of an insulation detecting device carrying out an insulation detecting method according to the present invention. A high voltage source (=direct current source) V composed of the number N of the batteries in series is isolated from a ground G of a low voltage system such as a microcomputer 10. The microcomputer 10 works as a voltage measuring member, a first controlling member, a calculating member, and a controlling member in claims.

As shown in FIG. 4, the insulation detecting device includes a bipolar capacitor C, a first switch SW1 for connecting an anode of the high voltage source V to an end of the capacitor C, and a second switch SW2 for connecting a cathode of the high voltage source V to the opposite end of the capacitor C.

The microcomputer 10 measures a voltage by A/D converting a voltage supplied to input ports A/D1 and A/D2. Further, the microcomputer 10 includes a warning mechanism for driving a warning part 20 when an insulation failure is detected. The insulation detecting device includes a third switch SW3 for connecting the one end of the capacitor to the input port A/D1, and a fourth switch SW4 for connecting the opposite end of the capacitor to the ground G.

The insulation detecting device also includes a first resistor R1 interposed between the third switch SW3 at the input port A/D1 side and the ground G, and a second resistor R2 interposed between the fourth switch SW4 at the ground G side and the ground G.

Further, a voltage is supplied to the input port A/D1 via a protection circuit 11. This protection circuit 11 includes a protection resistor Rp1 interposed between the first resistor R1 at the third switch SW3 side and the input port A/D1, and a clamp diode Dc interposed between the protection resistor Rp1 at the input port A/D1 side and the ground G.

The protection resistor Rp1 works as a current limiting resistor and protects the input port A/D1 from an overcurrent. Further, the clamp diode Dc protects the input port A/D1 from a huge positive or negative voltage.

The insulation detecting device includes a resistor switching circuit 12 interposed between a contact between the first and the third switches SW1, SW3 and the capacitor C. The resistor switching circuit 12 is structured by connecting series circuits in parallel. One series circuit is composed of a first diode D1 connected in a forward direction from the contact between the first and the third switches SW1, SW3 to the capacitor C, and a first switching resistor Rc1. The other series circuit is composed of a second diode connected in a reverse direction against the first diode D1, and a second switching resistor Rc2.

Namely, the first and the second diodes D1, D2 works as a selecting member. The selecting member selects one of the first and the second switching resistor corresponding to the polarity direction of the capacitor, and connects the selected resistor to the contact between the contact between the first and the third switches SW1, SW3, and the capacitor C. Further, the switches SW1 to SW4 are controlled by the microcomputer 10 with, for example, an optical MOSFET for isolating from the high voltage source V. Incidentally, a reference number 13 indicates a reset circuit. When a reset switch SWr is closed, charge stored in the capacitor C can be rapidly discharged through a discharge resistor Rdc.

Further, input sides of the insulation detecting device are connected to the anode and cathode of the high voltage source V, and output side of the insulation detecting device includes a high voltage measuring circuit 30 connected to an input port A/D2 of the microcomputer 10. This high voltage measuring circuit 30 works for real time monitoring the voltage across the high voltage source V. The high voltage measuring circuit 30 works as a second voltage measuring member in claims.

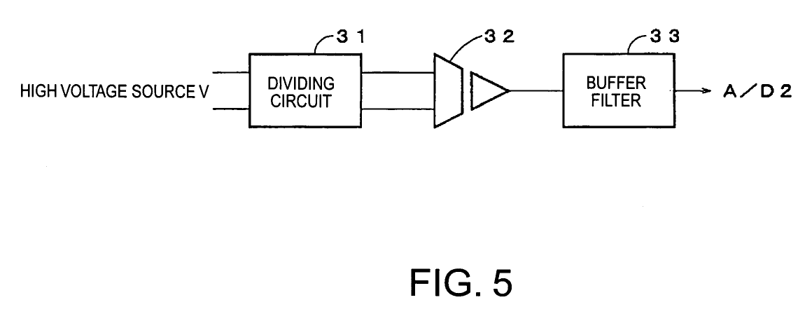

FIG. 5 is a block diagram showing a structure of a high voltage measuring circuit 30. The high voltage measuring circuit 30 includes a direct measuring system having a voltage dividing circuit 31, an isolating amplifier 32, and a buffer filter 33. The voltage dividing circuit 31 is connected to both ends of the high voltage source V, and divides the high voltage into a specific voltage. The isolating amplifier 32 isolates input and output of the divided voltage divided by the voltage dividing circuit 31 and amplifies the voltage. The buffer filter 33 blocks a noise of the output from the isolating amplifier 32 and supplies the output to the input port A/D2 of the microcomputer 10.

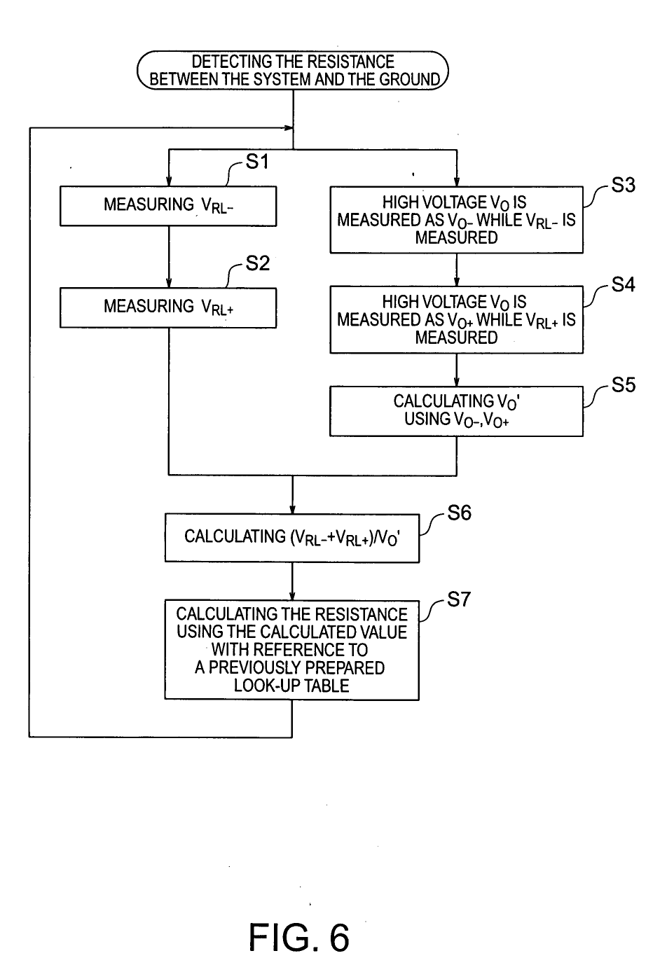

Next, an insulation detecting operation of the insulation detecting device according to the invention will be explained with reference to a flowchart of FIG. 6. First, the microcomputer 10 measures a voltage V_{RL-} corresponding to a value of a resistor RL− (step S1). This measurement is in detail done by followings. Initially, all the switches are open. Then, the microcomputer 10 closes the first and the fourth switches SW1, SW4 for a charging time T1. T1 is shorter than a time required for fully charging the capacitor C. Thus, a closed circuit is formed by the anode of the high voltage source V, a first switch SW1, a first diode D1, a first switching resistor Rc1, a capacitor C, a fourth switch SW4, a second resistor R2, a ground G, a resistor RL−between the cathode of the high voltage source V and the ground G, and the cathode of the high voltage source V. A voltage corresponding to a value of the resistor RL− is charged in the capacitor C.

Next, after opening the first switch SW1, the microcomputer 10 closes the third and the fourth switches SW3, SW4. Thus, a closed circuit is formed by the capacitor C, a second diode D2, a second switching resistor Rc2, the third switch SW3, the first resistor R1, the second resistor R2, and the fourth switch SW4. Thus, a voltage Vc across the capacitor C is divided by a ratio determined by the second switching resistor Rc2, the first resistor R1, and the second resistor R2, and supplied to the input port A/D1 of the microcomputer 10. The supplied divided voltage (Vc*R1/(Rc2+R1+R2)) is A/D converted to a digital value, and the value is inputted into the microcomputer 10 as a voltage V_{RL-} (first measuring voltage) corresponding to a value of the resistor RL−.

Next, the microcomputer 10 measures a voltage V_{RL+} corresponding to a value of the resistor RL+ between the anode of the high voltage source and the ground G (step S2). This measurement is in detail done by followings. The microcomputer 10 closes the reset switch SWr of the reset circuit 13 to fully discharge the capacitor C. Next, after opening the reset switch SWr and the fourth switch SW4, the microcomputer 10 closes the second and the third switches SW2, SW3 for the charging time T1. Thus, a closed circuit is formed by the anode of the high voltage source V, the resistor RL+, the ground G, the first resistor R1, the third switch SW3, the first diode D1, the first switching resistor Rc1, the capacitor C, the second switch SW2, and the cathode of the high voltage source V, and a voltage corresponding to a value of the resistor RL+ is charged in the capacitor C.

Next, after opening the second switch SW2, the microcomputer 10 closes the third and the fourth switches SW3, SW4. Thus, the voltage Vc across the capacitor C is divided by a ratio determined by the second switching resistor Rc2, the first and the second resistor R1, R2, and supplied to the input port A/D1 of the microcomputer 10. The supplied divided voltage is A/D converted to a digital value, and the value is inputted into the microcomputer 10 as the voltage V_{RL+} (second measuring voltage) corresponding to the value of the resistor RL+.

Incidentally, the first and the second resistors R1, R2 are the same value (R1=R2). Thus, the charging resistor (Rc1+R2) when the first and the fourth switches SW1, SW4 are closed and the capacitor C is charged by the voltage corresponding to the resistor RL− and the charging resistor (Rc1+R1) when the second and the third switches SW2, SW3 are closed and the capacitor C is charged by the voltage corresponding to the resistor RL+are the same.

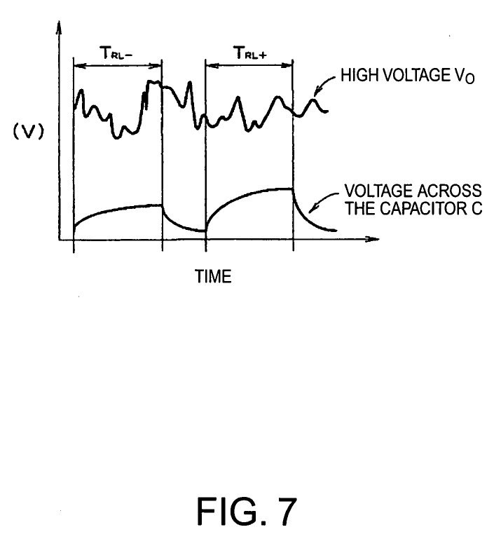

On the other hand, as shown in FIG. 7, during the measuring period T_{RL-} for measuring the voltage V_{RL-} corresponding to the resistor RL−, the microcomputer 10 fetches the outputs of the high voltage measuring circuit 30 at a specific timing (for example, 10 msec) several times (for example, ten data) via the input port A/D2. The microcomputer 10 calculates for averaging a plurality of fetched data, and the calculated average is treated as a voltage V₀ across the high voltage source V during the measuring period T_{RL-} (step S3).

Next, as shown in FIG. 7, during the measuring period T_{RL+} for measuring the voltage V_{RL+} corresponding to the resistor RL+, the microcomputer 10 fetches the outputs of the high voltage measuring circuit 30 at a specific timing (for example, 10 msec) several times (for example, ten data) via the input port A/D2. The microcomputer 10 calculates for averaging a plurality of fetched data, and the calculated average is treated as a voltage Vₒ₊ across the high voltage source V during the measuring period T_{RL-} (step S4).

Next, the microcomputer 10 processes (for example, averaging) the voltage V₀₋ and V₀₊ and fetches the processed data as a voltage V₀′ across the high voltage source (step S5).

Next, the microcomputer 10 divides a sum of V_{RL-} and V_{RL+} by the measured voltage V₀′ (V_{RL-}+V_{RL+}/V₀′) (step S6). Next, the microcomputer 10 calculates the resistance between the high voltage source V and the ground G using a look up table of the calculated value and the resistance previously stored in the internal memory (step S7).

Thus, the resistance between the high voltage source V and the ground G can be calculated. After calculating the resistance, the microcomputer 10 compares the calculated resistance with a threshold value previously stored in the internal memory. If the calculated resistance is smaller than the threshold value, a warning part 20 warns that there is an insulation failure.

As mentioned the above, according to the present invention, the insulation detecting device includes the high voltage measuring circuit 30 for real time measuring the voltage across the high voltage source V, so that including the voltage changing state which conventionally cannot be measured, in all the vehicle running state, the insulation can be detected.

Conventionally, the voltage across the high voltage source V is measured before measuring the voltages corresponding to the resistors RL− and RL+. According to the present invention, the voltage across the high voltage source V and the voltages corresponding to the resistors RL−, RL+ are respectively measured at the same time. Therefore, the high voltage change is always included in the calculated value, and the resistance to the ground can be measured even when the high voltage is changed. Further, since the high voltage change reflects the calculation of the resistance to the ground, the detecting accuracy of the resistance to the ground is improved. Further, since the conventional high voltage measuring cycle is canceled, responsibility and noise tolerance are improved. Further, process options for such as noise suppression are expanded.

Further, noise tolerance of the whole device can be improved more than the conventional device. Because there is a problem that as a capacitor attached to an outside of the insulation detecting device for canceling noise between the high voltage source V and the ground G increases, the measuring time for measuring the voltages corresponding to the resistors RL− and RL+ should be increases for measuring accurately. According to the present invention, this extension measuring time can be absorbed by canceling the measuring of the voltage across the high voltage source V which is conventionally measured before measuring the voltages corresponding to the resistors RL− and RL+. Therefore, options for selecting the capacitor for canceling noise are increased and the noise tolerance of the whole device is increased.

The second embodiment has been explained, however, the present invention is not limited to this.

For example, the high voltage measuring circuit 30 uses the direct measurement system with the isolating amplifier 32, but can use another system.

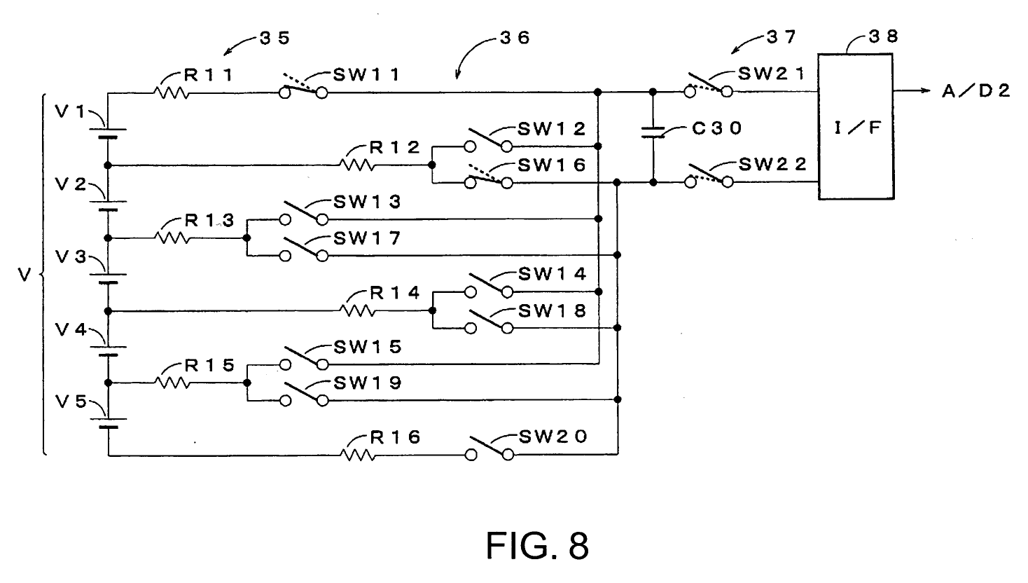

FIG. 8 is a circuit diagram showing another system of the high voltage measuring circuit 30. In FIG. 5, the high voltage measuring circuit 30 includes a flying capacitor system having a capacitor 30, a resistor circuit 35, a multiplexer 36, a sample switch circuit 37, and an interface circuit 38. The resistor circuit 35 has current limiting resistors R11 to R 16 for short protection, respectively connected to batteries V1 to V5. The multiplexer 36 is connected to both ends of the capacitor C30 via the current limiting resistors R11 to R 16, and has switches SW11 to SW20 opened or closed by control of the microcomputer 10. The sample switch circuit 37 includes switches SW21, SW22 for switching the voltage across the capacitor C30 to the interface circuit 38. The interface circuit converts the voltage across the capacitor C30 to the voltage against the ground G, and supplies the voltage to the input port A/D2 of the microcomputer 10.

During the measuring period for measuring voltages corresponding to the resistors RL− and RL+, the high voltage measuring circuit 30 shown in FIG. 5 measures the voltages of batteries V1 to V5 by sequentially closing the switches SW11 to SW20 of the multiplexer 36, and closing the sample switch circuit 37. Then, the high voltage measuring circuit 30 sums up the measured values of the batteries V1 to V5. Then, the high voltage measuring circuit 30 inputs the voltage V₀ across the high voltage source V for a specific sampling timing and several times to the microcomputer 10. Then, the high voltage measuring circuit 30 averages the inputted data, and the average is inputted as the voltage V₀ across the high voltage source V.

For example, when measuring the battery V1, from an initial state that all the switches are open, the switches SW11, SW16 of the multiplexer 36 are closed to charge the voltage of the battery V1 to the capacitor C30. Then, by opening the switches SW11, SW 16 and closing the switches SW21, SW22 of the sample switch circuit 37, the voltage across the capacitor C30 is supplied to the input port A/D2 of the microcomputer 10 via the interface circuit 38. The supplied voltage across the capacitor C30 is A/D converted to the digital value and the value is inputted into the microcomputer 10 as a voltage of the battery V1.

Similarly, the voltages of the battery V2 to V5 are sequentially inputted into the microcomputer 10 by closing combinations of the switches SW 12 and SW17, SW13 and SW18, SW14 and SW19, SW15 and SW20.

Further, in the above embodiment, the voltage V₀ across the high voltage source V is calculated as the average, but another calculation method can be used. For example, during the measurement of the voltages corresponding to the resistors RL− and RL+, the insulation detecting device may calculate an intermediate value between the maximum and the minimum values of the monitored high voltage change, and the calculated intermediate value may be determined as the voltage V₀ across the high voltage source V. Further, proper weights may be assigned to the averages of the high voltage monitored during the measurements of the voltage corresponding to the resistors RL−, RL+. The calculated weight assigned value may be determined as the voltage V₀ across the high voltage source V. This calculated weight assigned value is, for example, calculated by a difference between a measured resistance to the ground G when a vehicle is running, and the known resistance to the ground G.

1. An insulation detecting method for detecting a resistance between a ground and an insulated direct current source comprising the steps of:
a first measurement step to determine a voltage V₀ across the direct current source by measuring a voltage across a capacitor connected to an anode and a cathode of the direct current voltage source;
a second measurement step to determine a first measurement voltage V_{RL-} by measuring a voltage across a capacitor connected to the anode of the direct current voltage source and the ground;
a third measurement step to determine a second measurement voltage V_{RL+} by measuring a voltage across a capacitor connected to the cathode of the direct current voltage source and the ground;
a detecting step to apply an alternating signal to the anode or the cathode of the direct current source via a detecting resistor and a coupling capacitor and to detect a change of a voltage amplitude of the alternating signal appeared across the detecting resistance as a voltage change of the direct current source;
a correction step to calculate a corrected first measurement voltage V_{RL-} by correcting the first measurement voltage V_{RL-} calculated at the second measurement step based on the voltage change of the direct current source detected at the detecting step, and to calculate a corrected second measurement voltage V_{RL+}′ by correcting the second measurement voltage V_{RL+} calculated at the third measurement step, and
a resistance calculating step for calculating a resistance between the direct current source and the ground based on the corrected first measurement voltage V_{RL-}′, the corrected second measurement voltage V_{RL+}′ calculated at the correction step, and the voltage V₀ across the direct current source calculated at the first measurement step.

2. The insulation detecting method as claimed in claim 1
wherein the detecting step including:
a first average measurement step to measure a first average of a voltage amplitude of the alternating signal appeared across the detecting resistance while the first measurement step proceeds;
a second average measurement step to measure a second average of the voltage amplitude of the alternating signal appeared across the detecting resistance while the second measurement step proceeds;
a third average measurement step to measure a third average of the voltage amplitude of the alternating signal appeared across the detecting resistance while the third measurement step proceeds; and
a correction value calculating step to calculate a ratio of the first average to the second average as a first correction value corresponding to the voltage change across the direct current source and to calculate a ratio of the first average to the third average as a second correction value corresponding to the voltage change across the direct current source,
wherein the correction step calculates the corrected first measurement voltage V_{RL-}′ by correcting the first measurement voltage V_{RL-} based on the first correction value, and calculates the corrected second measurement voltage V_{RL+} by correcting the second measurement voltage V_{RL+} based on the second correction value, and
the resistance calculating step calculates the resistance between the direct current source and the ground based on the corrected first measurement voltage V_{RL-}′, the corrected second measurement voltage V_{RL+}′, and the voltage V₀ across the current voltage source.

3. An insulation detecting device for detecting a resistance between a ground and an insulated direct current source comprising:
a capacitor;
a voltage measuring member for measuring a voltage across the capacitor;
a first switch connected between an anode of the direct current source and one end the capacitor;
a second switch connected between a cathode of the direct current source and an opposite end of the capacitor;
a third switch connected between the one end of the capacitor and the voltage measuring member;
a fourth switch connected between the opposite end of the capacitor and the ground;
a control member for selectively closing the first to fourth switches,
an alternating signal generating member;
a detecting resistor and a coupling capacitor for applying an alternating signal generated by the alternating signal generator to the direct current source;
a detecting member for detecting a fluctuation component of a voltage amplitude of the alternating signal appeared across the detecting resistor as a change of the voltage across the direct current source;
a correction member for calculating a corrected first measurement voltage V_{RL-}′ by correcting a first measurement voltage V_{RL-} measured by measuring a voltage with the voltage measuring member across the capacitor charged by the controlling member closing the first and the fourth switches, and for calculating a corrected second measurement voltage V_{RL+}′ by correcting a second measurement voltage V_{RL+} measured by measuring the voltage of the capacitor charged by the controlling member closing the second and the third switches based on the change of the voltage across the direct current source; and
a calculating member for calculating a resistance between the direct current source and the ground based on the corrected first measurement voltage V_{RL-}′, the corrected second measurement voltage V_{RL+}′, and a voltage across the direct current source V₀ measured by measuring the voltage across the capacitor charged by the controlling member closing the first and the second switches.

4. The insulation detecting device as claimed in claim 3,
wherein the detecting member includes:
a first average measuring member for measuring a first average of a voltage amplitude of the alternating signal appeared across the detecting resistor while the voltage measuring member measures the voltage V₀ across the direct current source;
a second average measuring member for measuring a second average of the voltage amplitude of the alternating signal appeared across the detecting resistor while the voltage measuring member measures the first measurement voltage V_{RL-};
a third average measuring member for measuring a third average of the voltage amplitude of the alternating signal appeared across the detecting signal while the voltage measuring member measures the second measurement voltage V_{RL+}; and
a correction value calculating member for calculating a ratio of the first average to the second average as a first correction value corresponding to the change of the voltage across the current voltage source, and for calculating a ratio of the first average to the third average as a second correction value corresponding to the based on the change of the voltage across the direct current source,
wherein the correction member calculates the corrected first measurement voltage V_{RL-}′ by correcting the first measurement value V_{RL-} based on the first correction value, and calculates the corrected second measurement value V_{RL+}′ by correcting the second measurement value V_{RL+} based on the second correction value, and
the resistance calculating member calculates the resistance between the direct current source and the ground based on the corrected first measurement voltage V_{RL-}′, the corrected second measurement voltage V_{RL+}′, and the voltage V₀ across the direct current source.

5. The insulation detecting device as claimed in claim 4, further comprising:
a first resistor connected between a contact between the third switch and the voltage measuring member and the ground;
a second resistor connected between the fourth switch and the ground;
a first and a second switching resistors connected between a contact between the first and the third switches and one end of the capacitor; and
a selecting member for selecting one of the first and the second switching resistors corresponding to a polarity direction of the capacitor, and connecting the one of the first and the second switching resistors between the contact between the first and the third switches and the one end of the capacitor.

6. An insulation detecting method for detecting a resistance between a ground and an insulated direct current source comprising the steps of:
a first measurement step to determine a first measurement voltage V_{RL-} by a first voltage measuring member measuring a voltage across a capacitor connected to an anode of the direct current voltage source and the ground;
a second measurement step to determine a second measurement voltage V_{RL+} by the first voltage measuring member measuring a voltage across the capacitor connected to a cathode of the direct current voltage source and the ground;
a third measurement step to determine a voltage V₀′ across the direct current source by a second voltage measuring member connected to both ends of the direct current source while the first and the second measuring steps proceed; and
a calculating step for calculating a resistance between the direct current source and the ground based on the first voltage V_{RL-}, the second voltage V_{RL+}, and the voltage V₀′ across the direct current source.

7. An insulation detecting device for detecting a resistance between a ground and an insulated direct current source comprising:
a capacitor;
a first voltage measuring member for measuring a voltage across the capacitor;
a first switch connected between an anode of the direct current source and one end of the capacitor;
a second switch connected between a cathode of the direct current source and an opposite end of the capacitor;
a third switch connected between the one end of the capacitor and the first voltage measuring member;
a fourth switch connected between the opposite end of the capacitor and the ground;
a control member for selectively closing the first to fourth switches;
a second measuring member connected to both ends of the direct current source for measuring a voltage V₀′ across the direct current source; and
a calculating member for calculating a resistance between the direct current source and the ground based on a first measurement voltage V_{RL-} measured by measuring a voltage with the voltage measuring member across the capacitor charged by the controlling member closing the first and the fourth switches, a second measurement voltage V_{RL+} measured by measuring the voltage of the capacitor charged by the controlling member closing the second and the third switches, and the voltage V₀′ across the direct current source,
wherein the second measuring member measures the voltage V₀′ across the direct current source while the first measuring member measures the first measurement voltage V_{RL-} and the second measurement voltage V_{RL+}.

8. The insulation detecting device as claimed in claim 7 further comprising:
a first resistor connected between a contact between the third switch and the first voltage measuring member and the ground;
a second resistor connected between the fourth switch and the ground;
a first and a second switching resistors connected between a contact between the first and the third switches and one end of the capacitor; and
a selecting member for selecting one of the first and the second switching resistors corresponding to a polarity direction of the capacitor, and connecting the one of the first and the second switching resistors between the contact between the first and the third switches and the one end of the capacitor.
